(19) United States
(12) Patent Application Publication
(10) Pub. No.: US 2012/0199981 A1
(43) Pub. Date: Aug. 9, 2012

(54) SEMICONDUCTOR DEVICE AND METHOD OF FABRICATING THE SEMICONDUCTOR DEVICE

(76) Inventors: Se-young Jeong, Suwon-si (KR); Ho-geon Song, Suwon-si (KR); Ju-il Choi, Suwon-si (KR); Jae-hyun Phee, Gyeyang-gu (KR)

(21) Appl. No.: 13/364,678

(22) Filed: Feb. 2, 2012

(30) Foreign Application Priority Data
Feb. 9, 2011 (KR) 10-2011-0011613

(51) Int. Cl. H01L 23/48; H01L 21/50

(52) U.S. Cl. 257/774; 257/773; 438/109; 257/E23.011; 257/E21.499

(57) ABSTRACT

A semiconductor device includes a first device including a first substrate and a first external connection terminal for connecting outside the first device; a second device stacked on the first device, the second device including a second substrate and a second external connection terminal for connecting outside the second device; an adhesive pattern disposed between the first device and second device, the adhesive pattern disposed in locations other than locations where the first external connection terminal and second external connection terminal are disposed, and the adhesive pattern causing the first device and second device, when stacked, to be spaced apart by a predetermined distance; and a plated layer disposed between and electrically and physically connecting the first external connection terminal and the second external connection terminal.

### CROSS-REFERENCE TO RELATED APPLICATIONS

This application claims the benefit of Korean Patent Application No. 10-2011-0011613, filed on Feb. 9, 2011, in the Korean Intellectual Property Office, the disclosure of which is incorporated herein in its entirety by reference.

### BACKGROUND

The disclosed embodiments relate to semiconductor devices in which more than two semiconductor devices are stacked on each other, and more particularly, to semiconductor devices having a warpage prevention adhesive pattern in a connecting part between two semiconductor devices and a method of fabricating the semiconductor devices.

The trend in the electronic industry is toward manufacturing light weight, small sized, high speed, and high performance electronic products at low cost and providing these low cost electronic products to consumers. According to this trend, stacked multi-chip package technology or system in package technology has been developed. In general, stacked multi-chip package technology or system in package technology uses a through-substrate via (TSV), such as a through-silicon via instead of a conventional wire as a connection tool between an upper semiconductor device and a lower semiconductor device.

A stacked multi-chip package or a system in package may perform functions of a plurality of unit semiconductor devices in a single semiconductor package. The thickness of the stacked multi-chip package or the system in package may be thicker than that of a semiconductor package including a single semiconductor chip. However, depending on the progress of technology for reducing a thickness by grinding a bottom side of the semiconductor chip, the thickness of the stacked multi-chip package or the system in package has been reducing and has come closer to the thickness of the semiconductor package including a single semiconductor chip.

### SUMMARY

The disclosed embodiments provide, in the case of connecting upper and lower thin semiconductor devices to each other, a semiconductor device for suppressing a warpage defect by using a warpage prevention adhesive pattern and for connecting input/output terminals of the upper and lower semiconductor devices by using an adhesive joint formed by electroless plating.

The disclosed embodiments also provide, in the case of connecting upper and lower thin semiconductor devices to each other, a method of fabricating a semiconductor device for suppressing a warpage defect by using a warpage prevention adhesive pattern and for connecting input/output terminals of the upper and lower semiconductor devices by using an adhesive joint formed by electroless plating.

The inventive concept is not limited to the aforementioned concept, and other concepts not mentioned above will be clearly understood by those of ordinary skill in the art from the following description.

In one embodiment, a semiconductor device includes a first device including a first substrate and a first external connection terminal for connecting outside the first device; a second device stacked on the first device, the second device including a second substrate and a second external connection terminal for connecting outside the second device; an adhesive pattern disposed between the first device and second device, the adhesive pattern disposed in locations other than locations where the first external connection terminal and second external connection terminal are disposed, and the adhesive pattern causing the first device and second device, when stacked, to be spaced apart by a predetermined distance; and a plated layer disposed between and electrically and physically connecting the first external connection terminal and the second external connection terminal.

In another embodiment, a semiconductor package includes a first substrate including a first external connection terminal disposed thereon; a second substrate including a second external connection terminal disposed thereon; a plated layer disposed between and electrically and physically connecting the first external connection terminal and the second external connection terminal; and a support structure separating the first device and the second device by a predetermined distance. The support structure is configured to prevent warping of the first and second substrate during a formation of the plated layer.

In a further embodiment, a method of fabricating a semiconductor device includes: providing a first device including a first substrate and a first external connection terminal at a first surface of the first device; forming spacers made of an insulating material on the first surface of the first device at a location other than a location where the first external connection terminal is disposed; providing a second device stacked on the first device, the second device including a second substrate and a second external connection terminal at a first surface of the second device, wherein the first surface of the first device faces the first surface of the second device, and wherein the spacers cause the first device and second device, when stacked, to be spaced apart by a predetermined distance; and forming a plated layer between the first external connection terminal and the second external connection terminal. The plated layer physically and electrically connects the first external connection terminal and the second external connection terminal.

### BRIEF DESCRIPTION OF THE DRAWINGS

Exemplary embodiments will be more clearly understood from the following detailed description taken in conjunction with the accompanying drawings in which:

FIGS. 1 through 4 are cross-sectional views for illustrating a method of fabricating a semiconductor device having a warpage prevention adhesive pattern according to an exemplary embodiment;

FIG. 5 is a cross-sectional view of a semiconductor device having a warpage prevention adhesive pattern according to an exemplary embodiment;

FIG. 6 is an exemplary cross-sectional view for illustrating how a plurality of adhesive joints are formed by electroless plating illustrated in FIG. 4;

FIG. 7 is a cross-sectional view for illustrating an example of a modification of FIG. 6;

FIG. 8 is a cross-sectional view for illustrating another example of a modification of FIG. 6;

FIG. 9 is a cross-sectional view of a semiconductor device having a warpage prevention adhesive pattern according to another exemplary embodiment;

FIG. 10 is a cross-sectional view of a semiconductor device having a warpage prevention adhesive pattern according to another exemplary embodiment;

FIG. 11 is a cross-sectional view of a semiconductor device having a warpage prevention adhesive pattern according to another exemplary embodiment;

FIG. 12 is a cross-sectional view of a semiconductor device having a warpage prevention adhesive pattern according to another exemplary embodiment;

FIGS. 13 through 15 are cross-sectional views for illustrating a method of fabricating a semiconductor device having a warpage prevention adhesive pattern according to another exemplary embodiment;

FIG. 16 is a cross-sectional view for illustrating an exemplary semiconductor device manufactured by using a method of fabricating a semiconductor device having a warpage prevention adhesive pattern according to an exemplary embodiment;

FIGS. 17 through 19 are a plan view and system block diagrams showing exemplary electronic devices to which a semiconductor device fabricated according to certain embodiments may be applied; and

FIG. 20 is a perspective view showing an exemplary electronic device to which a semiconductor device fabricated by certain embodiments may be applied.

### DETAILED DESCRIPTION OF THE EMBODIMENTS

Hereinafter, the present disclosure will be described more fully with reference to the accompanying drawings, in which exemplary embodiments are shown. The invention may, however, be embodied in many different forms and should not be construed as being limited to the exemplary embodiments set forth herein. In the drawings, lengths and sizes of layers and regions may be exaggerated for clarity.

It will be understood that when an element is referred to as being “on” another element, the element can be directly on the other element or can be directly on intervening elements. In contrast, when an element is referred to as being “directly on” another element, there are no intervening elements present. Other words used to describe the relationship between elements should be interpreted in a like fashion (e.g., “between,” versus “directly between,” “adjacent,” versus “directly adjacent,” “connected to,” “coupled to,” etc.).

It will be understood that, although the terms first, second, third, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the present invention.

As used herein, the singular forms “a”, “an” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs.

FIGS. 1 through 4 are cross-sectional views for illustrating an exemplary method of fabricating a semiconductor device having a warpage prevention adhesive pattern according to one embodiment.

Referring to FIG. 1, a first device, such as a first semiconductor device 100 is provided. The first device may be, for example, a semiconductor chip (i.e., a memory or logic chip, an interposer chip, etc.), a group of stacked semiconductor chips, a semiconductor package, a package substrate, a circuit board, etc. In FIG. 1, a semiconductor chip in which a circuit pattern 13 is formed at a first side, such as upper side 11 of a semiconductor substrate 10, is prepared. The circuit pattern 13 may disposed, for example, at a first surface of the substrate 10. The semiconductor substrate 10 may be part of a wafer that includes integrated circuitry, or may be an interposer which is formed with a silicon material and is used when depositing multichips. The first semiconductor device 100 in which the circuit pattern 13 is formed, may further include a terminal, such as an input/output (I/O) terminal 20 for expanding a function of the circuit pattern 13 to the outside. The I/O terminal 20 of the first semiconductor device 100 may be, for example, a through silicon via (TSV) having a form that passes through the semiconductor substrate 10. The inside of the TSV 20 may have a structure in which an insulation layer 22, a seed layer 24, and a via contact 26 are sequentially formed.

Furthermore, a conductive pad, such as upper I/O pad 40, which is connected to the I/O terminal 20, may be formed with a conductive material on the upper side 11 of the semiconductor substrate 10, and another conductive pad, such as lower I/O pad 60 may be formed with the conductive material on a lower side 12 of the semiconductor substrate 10. The input/output (I/O) terminal 20, upper I/O pad 40, and/or lower I/O pad 60 may thus form an external connection terminal for connecting outside the first semiconductor device 100. The lower side 12 of the semiconductor substrate 10 may be covered by a protection layer 30 which includes a first insulation layer 32 and a second insulation layer 34 and exposes the lower I/O pad 60 to the outside.

In a method of fabricating a semiconductor device having a warpage prevention adhesive pattern according to one embodiment, as illustrated in FIG. 1, an adhesive layer 70 for forming a warpage prevention adhesive pattern is formed on the upper side 11 of the semiconductor substrate 10, with a thickness sufficient to extend past a top of the upper I/O pad 40. The adhesive layer 70 may be, for example, a non-conductive insulation material or may be a thermosetting material in which an adhesive power is strengthened by heat.

To implement a multi-chip package (MCP) or a system in package (SIP), the lower side 12 of the semiconductor substrate 10 may be ground, that is, partially removed beforehand. In certain embodiments, the thickness of the first semiconductor device 100 may be in the range of 30 μm through 120 μm, and the first semiconductor device 100 may be very vulnerable to a warpage defect during handling or processing.

Accordingly, in the case of electrically and physically connecting semiconductor devices vulnerable to the warpage defect to each other in upper and lower directions, certain disclosed embodiments relate to a method of connecting I/O terminals of the semiconductor devices to each other with an adhesive joint formed by electroless plating, and of suppressing a warpage defect by a warpage prevention adhesive pattern.

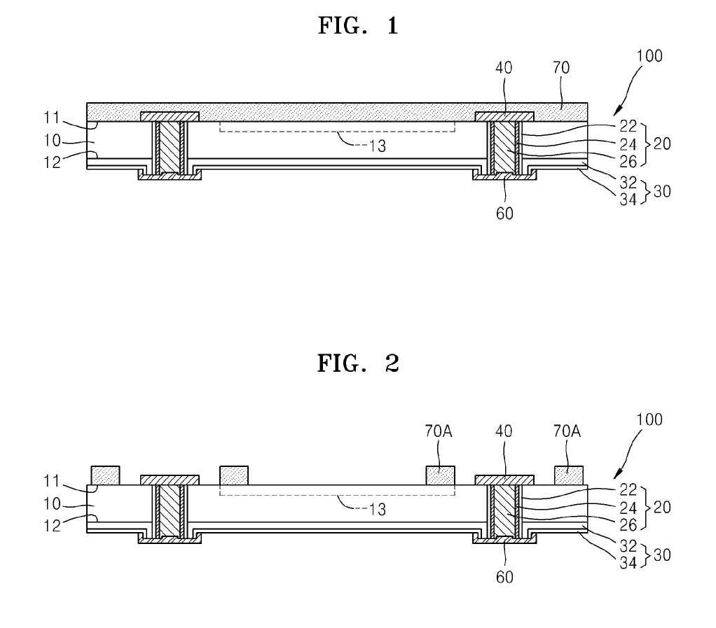

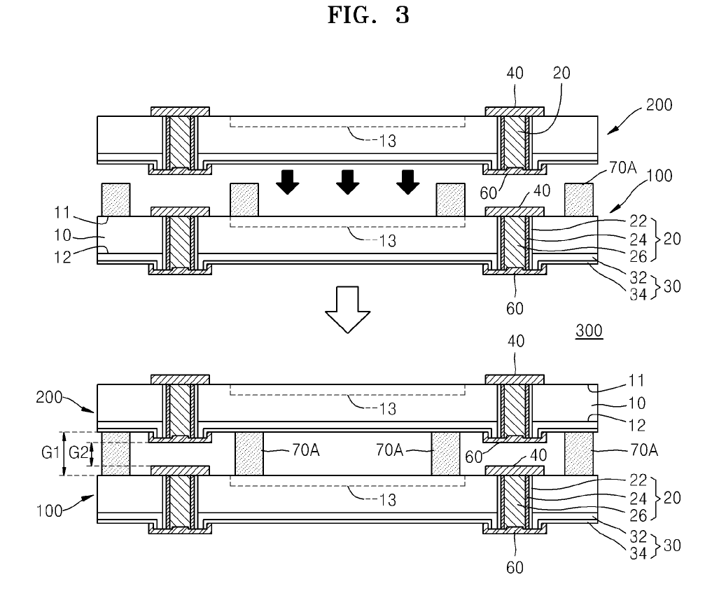

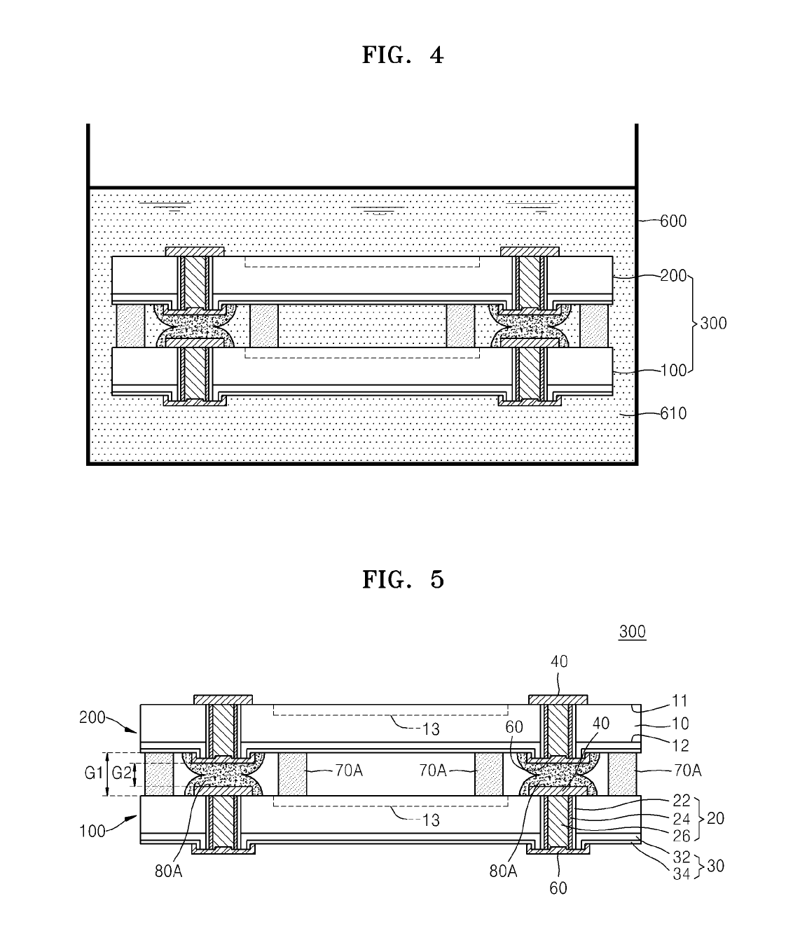

The structure of the first semiconductor device whose state is a wafer state is only an exemplary structure for explaining the disclosed embodiments, and a form of the I/O terminal 20 may be changed from the TSV to a bond pad including a general under bump metallurgy (USM) layer or the form of the I/O terminal 20 may be a pad re-distribution pattern connected to the bond pad. Furthermore, the first semiconductor device 100 may not be a semiconductor device whose state is a wafer state, but may be a printed circuit board for a semiconductor package, on which a semiconductor chip is mounted, or a unit semiconductor chip. For example, in one embodiment, the semiconductor device 100 shown in FIGS. 1 and 2 is a chip or die that is part of a first wafer that includes a plurality of chips or dies arranged in an array, and the semiconductor device 200 shown in FIGS. 3 and 4 a chip or die that is part of a second wafer that also includes a plurality of chips or dies arranged in an array, and the first wafer is stacked on the second wafer. However, in another embodiment, the semiconductor devices 100 and 200 are singulated devices that have been cut from a wafer and are thus each unit semiconductor devices. The structures of the upper and lower I/O pads 40 and 60, which are connected to the I/O terminal 20, and the structure of the insulation layer 30, may be changed into many different structures within the range of the disclosed concepts.

Referring to FIG. 2, an adhesive pattern, such as warpage prevention adhesive pattern 70A is formed by performing a photolithography process for the adhesive layer 70 in the first semiconductor device 100. For example, first, a photoresist (not shown) is deposited on the adhesive layer 70 of the first semiconductor device 100, and an exposure and development process is performed by using a mask. Then, by performing a dry-etching or wet-etching process, the warpage prevention adhesive pattern 70A is formed in a region other than the region in which the upper I/O pad 40 is formed, in the upper side 11 of the first semiconductor device 100. The warpage prevention adhesive pattern 70A forms a rigid support structure that helps physically support the devices stacked on each other and therefore helps avoid or prevent warping of the devices during the manufacturing process. The pattern may include, for example, a group of spacers, such as pillars, bars, or other shaped structures that extend a predetermined distance beyond a surface of the substrate 10 and thus have a particular height or thickness. The layout of the warpage prevention adhesive pattern 70A, and the width, and the height of the individual portions (i.e., pillars, bars, etc.) of the warpage prevention adhesive pattern 70A may be changed and optimized depending on the structure and the characteristics of semiconductor devices to be connected to each other in the upper and lower directions.

Referring to FIG. 3, in one embodiment, a second semiconductor device 200 having the same structure as one of the first semiconductor device 100 is prepared. Next, the first and second semiconductor devices 100 and 200 are lined up and connected to each other such that the circuit patterns 13 of the first and second semiconductor devices 100 and 200 are directed upward.

Here, the first and second semiconductor devices 100 and 200 may be aligned so that the lower I/O pad 60 of the second semiconductor device 200 may be connected to the upper I/O pad 40 of the first semiconductor device 100. In one embodiment, after being lined up, a curing process applying heat to the first and second semiconductor devices 100 and 200 for a predetermined time is performed. As a result, an adhesive power of the warpage prevention adhesive pattern 70A is strengthened by heat, and thus the first and second semiconductor devices 100 and 200 are physically connected to each other in the upper and lower directions.

An interval G1 is formed by the warpage prevention adhesive pattern 70A between the connected first and second semiconductor devices 100 and 200, and an interval G2 is generated between the lower I/O pad 60 of the second semiconductor device 200 and the upper I/O pad 40 of the first semiconductor device 100. As such, an upper surface of the first semiconductor device 100 and a lower surface of the second semiconductor device 200 may be separated and spaced apart from each other by a first distance G1, and the lower I/O pad 60 of the second semiconductor device 200 and the upper I/O pad 40 of the first semiconductor device 100 may be separated and spaced apart by a second distance G2 less than G1. In one embodiment, the distance G1 and the distance G2 may each be greater than minimal distance needed to allow a plating liquid to permeate during electroless plating.

As mentioned above, in one embodiment, the lower sides 12 of the semiconductor substrates 10 in the first and second semiconductor devices 100 and 200 are ground beforehand, and thus each of the first and second semiconductor devices 100 and 200 has a thickness in the range of 30 μm through 120 μm and is very vulnerable to the warpage defect. However, because the first and second semiconductor devices 100 and 200 are connected to each other by the warpage prevention adhesive pattern 70A, the occurrence of the warpage defect may be suppressed during handling and processing of the first and second semiconductor devices 100 and 200. As such, some or all warpage is prevented or avoided.

In this embodiment, the first and second semiconductor devices 100 and 200 are connected to each other so that the upper sides 11 of the first and second semiconductor devices 100 and 200 are directed upward. However, the first and second semiconductor devices 100 and 200 may be connected to each other so that the upper sides 11 of the first and second semiconductor devices 100 and 200 are directed downward.

Next, a plating process, such as electroless plating for the connected semiconductor devices 100 and 200 is performed. In one embodiment, except for the lower and upper I/O pads 60 and 40 disposed in the connected sides of the first and second semiconductor devices 100 and 200, portions in which a conductive layer is exposed, such as the upper I/O pad 40 of the second semiconductor device 200 and the lower I/O pad 60 of the first semiconductor device 100 may be covered by a protection layer (not shown) so that plating is not formed thereon during the electroless plating.

Referring to FIG. 4, a resulting product of FIG. 3 is put into a plating tub 600 where the electroless plating is performed. For example, a plating liquid 610 including one of nickel, copper, gold, silver, tin, chrome, and palladium may be prepared inside the plating tub 600. Then, the electroless plating is performed for the connected first and second semiconductor devices 100 and 200. Here, the electroless plating is a method for plating through a chemical reaction and uses the principle in which metal ions included in the plating liquid 610 are deoxidized by receiving electrons and stick to the surface of an object to be plated.

This electroless plating may be applied to form a conductive layer of a bump surface formed on a bond pad and a conductive layer of a surface of a bond pad rearranging pattern, in a process of fabricating semiconductor devices.

As a result of the electroless plating, a plated layer including a one or more conductive interconnections, such as adhesive joints 80A (refer to FIG. 5) is formed on the lower I/O pad 60 of the second semiconductor device 200 and the upper I/O pad 40 of the first semiconductor device 100, and thus the lower I/O pad 60 of the second semiconductor device 200 and the upper I/O pad 40 of the first semiconductor device 100 are connected to each other through the adhesive joints 80A.

In the aforementioned method, semiconductor devices of the same kind and same structure are connected to each other. However, a method of fabricating a semiconductor device having a warpage prevention adhesive pattern may be applied to connecting semiconductors that are of a different kind and different structure to each other.

FIG. 5 is a cross-sectional view of a semiconductor device having a warpage prevention adhesive pattern according to an exemplary embodiment.

Referring to FIG. 5, a semiconductor device 300 having a warpage prevention adhesive pattern made by the method of FIGS. 1 through 4, may include a first semiconductor device 100, a second semiconductor device 200, a plurality of warpage prevention spacers 70A, and a plurality of adhesive joints 80A.

In one embodiment, the first semiconductor device 100 includes a circuit pattern 13 and an upper I/O pad 40 which is disposed on the upper side of the first semiconductor device 100. The second semiconductor device 200 includes a circuit pattern 13 and is connected to the first semiconductor device 100 and separated from the first semiconductor device 100 by a predetermined interval G1, and includes a lower I/O pad 60 which is disposed on the lower side of the second semiconductor device 200.

The plurality of warpage prevention spacers 70A are disposed in a predetermined interval G1 between the first semiconductor device 100 and the second semiconductor device 200. The plurality of adhesive joints 80A are formed by the electroless plating, are disposed in a predetermined interval G2 between the first semiconductor device 100 and the second semiconductor device 200, and connect the upper I/O pad 40 of the first semiconductor device 100 and the lower I/O pad 60 of the second semiconductor device 200 to each other.

Adhesive joints formed by a thermal compression method may be used instead of the adhesive joints 80A formed by the electroless plating according to the inventive concept.

The adhesive joints formed by the thermal compression method require a bonder which is often a high cost joining equipment and require a long processing time for one bonding. Accordingly, in the case of connecting semiconductors including the through silicon via (TSV) to each other, the adhesive joints formed by the thermal compression method may be very costly. Furthermore, in the case that bonding is performed using a solder when two semiconductor devices are connected to each other, an intermetallic compound (IMC) may be generated at the boundary between the two semiconductor devices, and thus an adhesive strength deteriorates.

However, in the semiconductor device 300 having the warpage prevention adhesive pattern according to certain disclosed embodiments, the occurrence of the warpage defect is suppressed during a process of handling or fabricating the semiconductor device 300 because the warpage prevention spacers 70A uphold the two semiconductor devices 100 and 200.

Furthermore, in the semiconductor device 300 having the warpage prevention spacers 70A according to certain embodiments, several hundred adhesive joints through several thousand adhesive joints may be simultaneously formed between two wafers or chips or between a wafer or chip and a printed circuit board by the electroless plating, without using an expensive bonder. Therefore, the adhesive joints formed by the electroless plating have an advantage compared with the adhesive joints formed by the thermal compression method in terms of cost saving.

In one embodiment, the semiconductor device 300 having the warpage prevention spacers 70A according to an embodiment of the inventive concept, uses the adhesive joints 80A including a single metal such as nickel, copper, gold, silver, tin, chrome, or palladium, and thus the semiconductor device 300 may suppress generation of the intermetallic compound (IMC), which may be a problem in the adhesive joints formed by the thermal compression method. Therefore, the semiconductor device 300 having the warpage prevention spacers 70A according to certain embodiments may realize a uniform and stable adhesive strength at the joint boundary of the two semiconductor devices.

In addition, the semiconductor device 300 having the warpage prevention spacers 70A according to certain embodiments may prevent performance deterioration of the semiconductor device due to prolonged exposure to a high processing temperature during the thermal compression, and thus the semiconductor device 300 may secure high reliability.

The embodiments shown in FIGS. 1-5 illustrate a case where two semiconductor devices 100 and 200 are stacked, but it is possible to make a structure in which more than two semiconductor devices are connected to each other by using the warpage prevention spacers 70A.

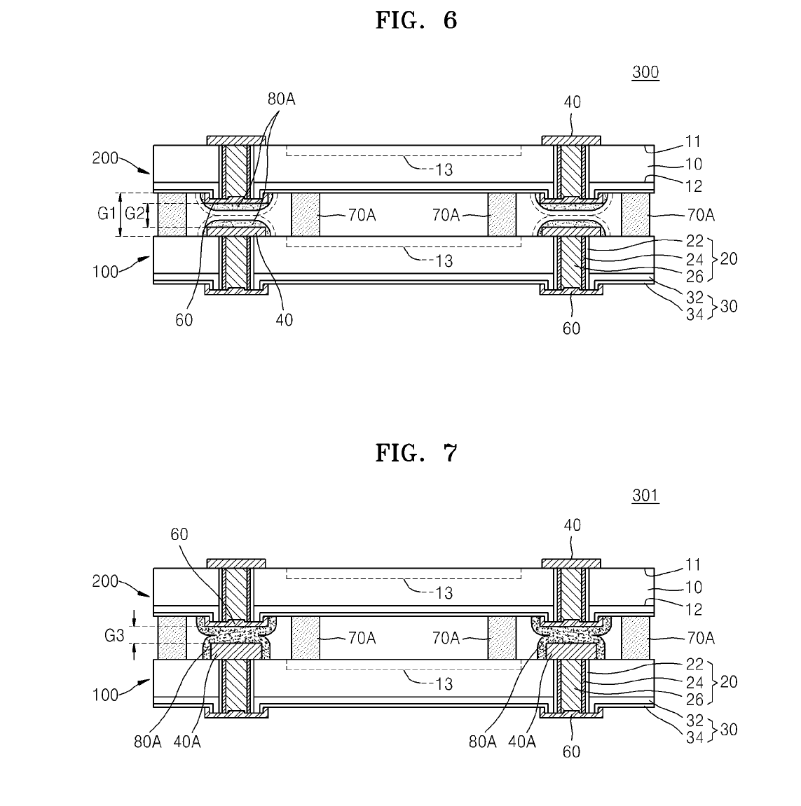

FIG. 6 is an exemplary cross-sectional view for illustrating how a plurality of adhesive joints are formed by electroless plating illustrated in FIG. 4.

Referring to FIG. 6, the adhesive joints 80A are formed by the electroless plating and formed on a surface of a conductive layer in the interval between the two semiconductor devices 100 and 200. Therefore, the adhesive joints 80A are formed not only on the lower side of the lower I/O pad 60 of the second semiconductor device 200 and on the upper side of the upper I/O pad 40 of the first semiconductor device 100 but also on left and right sides of the lower I/O pad 60 of the second semiconductor device 200 and on left and right sides of the upper I/O pad 40 of the first semiconductor device 100. They may extend, for example, to a boundary shown by the dotted lines between the TSVs of FIG. 6.

FIG. 7 is a cross-sectional view for illustrating an example of a modification of FIG. 6.

Referring to FIG. 7, in the semiconductor device 301 according to one embodiment, a form of the upper I/O pad 40A of the first semiconductor device 100 may be changed to have a larger (e.g., thicker) size into a form of a protrusion part to prevent a short circuit occurring between different adhesive joints 80A or prevent a manufacturing time of the adhesive joints 80A from increasing during the electroless plating. For example, in one embodiment, the protrusion part is a part in which the height of the upper I/O pad 40 of the first semiconductor device 100 is formed to be higher by changing the structure of the upper I/O pad 40 of the first semiconductor device 100. In this case, an interval G3 between the lower I/O pad 60 of the second semiconductor device 200 and the upper I/O pad 40A of the first semiconductor device 100 becomes narrower.

Accordingly, because the adhesive joints 80A are formed on the upper I/O pad 40A having the form of the protrusion part during the electroless plating, a electroless plating processing time may be reduced. Furthermore, the occurrence of a short between the adjacent adhesive joints 80A may be suppressed by reducing an extent of forming the adhesive joints 80A in lateral directions (e.g., left and right directions as shown in FIG. 7).

In the embodiment of FIG. 7, it is illustrated that the height of the upper I/O pad 40A of the first semiconductor device 100 is formed to be greater. However, the height of the lower I/O pad 60 of the second semiconductor device 200 also may be formed to be greater (and the height of the upper pad 40A of the first semiconductor device 100 the same, or also greater), and thus the interval G3 between the lower I/O pad 60 of the second semiconductor device 200 and the upper I/O pad 40A of the first semiconductor device 100 may be narrower.

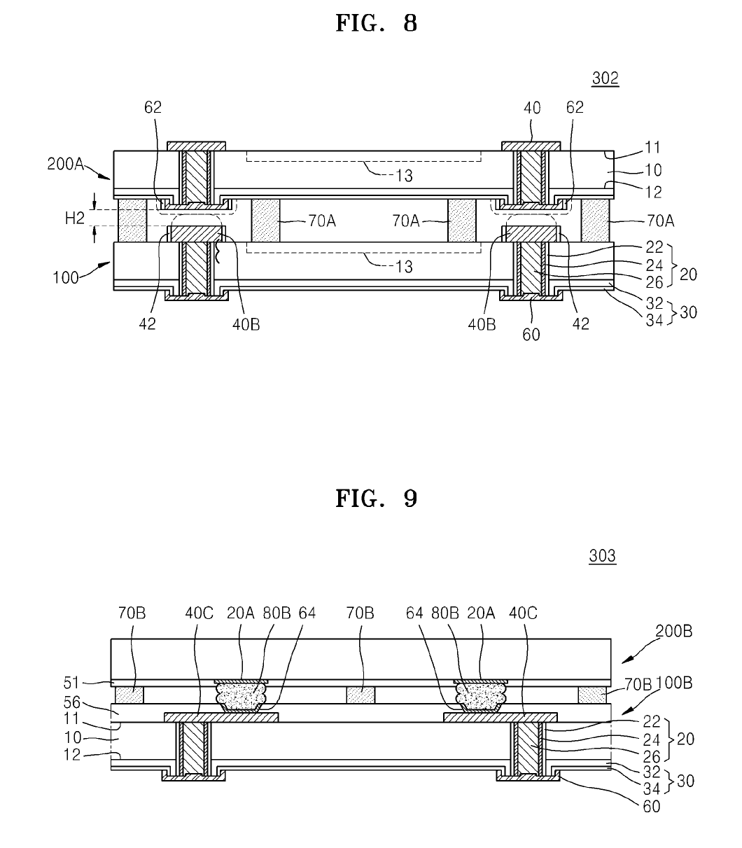

FIG. 8 is a cross-sectional view for illustrating another example of a modification of FIG. 6.

Referring to FIG. 8, in the semiconductor device 302 according to one embodiment, forming of the adhesive joints 80A in the lateral direction (e.g., in the left and right directions when viewed as a cross-section) may be limited to prevent a short from occurring. For this, the semiconductor device 302 may include separately an insulation layer 42 that surrounds the lateral sides of the upper I/O pad 40B of the first semiconductor device 100.

Accordingly, during the electroless plating, metal ions included in the plating liquid may be deposited only in an upper direction of the upper I/O pad 40B, which is an exposed conductive layer, of the first semiconductor device 100, and thus forming of the adhesive joints 80A in lateral directions may be suppressed.

On the other hand, instead of forming the insulation layer 42 to surround lateral sides of the upper I/O pad 40B of the first semiconductor device 100, an insulation layer 62 may be formed at the lateral sides of the lower I/O pad 60 of the second semiconductor device 200. Furthermore, the insulation layer 42 and insulation layer 62 may be both formed. Accordingly, a pitch between the I/O terminals may be designed to be smaller, and thus a larger number of I/O terminals may be designed in a limited area.

FIG. 9 is a cross-sectional view of a semiconductor device having a warpage prevention adhesive pattern according to another embodiment.

In the embodiment of FIG. 5, both the first and second semiconductor devices 100 and 200 have the TSV. However, referring to FIG. 9, the second semiconductor device 200B may be a unit semiconductor chip in which the TSV is not formed and only a bond pad 20A is formed. The second semiconductor device 200B may be, for example, a flip chip. The bond pad 20A of the second semiconductor device 200B which may be a unit semiconductor chip, may include an under bump metallurgy (UBM) layer (not shown). The second semiconductor device 200B may be a semiconductor device performing a different function to the function of the first semiconductor device 100B. For example, one of the devices may be a controller or logic chip and the other may be a memory chip.

Furthermore, the first semiconductor device 100B may have a structure in which a pad rearranging or redistribution pattern 40C, which is connected to the TSV, that is, the I/O terminal 20, is separately formed on the upper side 11 of the first semiconductor device 100B. In this case, the pad rearranging pattern 40C is covered by an insulation layer 56. Accordingly, the adhesive joints 80B are formed by the electroless plating so that the pad rearranging pattern 40C of the first semiconductor device 100B and the bond pad 20A of the second semiconductor device 200A are connected to each other. Here, the UBM layer 64 may be formed on a connection part of the pad rearranging pattern 40C. The semiconductor device 303 of FIG. 9 may have variously modified structures as illustrated in FIGS. 6 through 8.

FIG. 10 is a cross-sectional view of a semiconductor device having a warpage prevention adhesive pattern according to another embodiment.

The semiconductor device 300 having the warpage prevention adhesive pattern 70A illustrated in FIG. 5, may have a structure in which the two semiconductor devices 100 and 200 are both semiconductor chips including integrated circuits. However, as shown in FIG. 10, the first semiconductor device 100 located in the lower side may be replaced with a printed circuit board 400 for semiconductor packaging. The printed circuit board 400 may be, for example, a package substrate for mounting thereon a single stack of one or more semiconductor devices, or may be a module board or other board for mounting thereon a plurality of stacks of one or more semiconductor devices laterally separated from each other, for example in a matrix form.

Referring to FIG. 10, a semiconductor device 304 having a warpage prevention adhesive pattern 70C according to one embodiment uses the printed circuit board 400 for semiconductor packaging, in which printed circuit patterns 202, 204, 206 are formed internally, as the first semiconductor device. The printed circuit board 400 for semiconductor packaging may include a lower I/O pad 206, a middle pad 204, and an upper I/O pad 202. Furthermore, the lower I/O pad 206, the middle pad 204, and the upper I/O pad 202 may be connected to each other through a via contact 208. The lower I/O pad 206 and upper I/O pad 202 are terminals that connect externally to devices outside the printed circuit board 400. The structure of the printed circuit board 400 for semiconductor packaging is only an exemplary structure for explaining one embodiment, but the structure of the printed circuit board 400 may be modified in various forms within the scope of the present disclosure.

In the semiconductor device 304 having the warpage prevention adhesive pattern 70C according to one embodiment, the structure of the lower I/O pad 60 of the second semiconductor device 200B is the same as that of the second semiconductor device 200 illustrated in FIG. 5, but the structure of the upper I/O pad of the second semiconductor device 200B have a form of the pad rearranging pattern 40C connected to the TSV 20 which is the I/O terminal. In the case where another semiconductor device is not stacked on the pad rearranging pattern 40C, that is, the upper I/O pad of the semiconductor device 200B, an insulation layer 51 may be covered on the upper side 11 of the semiconductor substrate 10 to prevent the pad rearranging pattern 40C being shorted with another conductive material.

In the semiconductor device 304 having the warpage prevention adhesive pattern 70C according to one embodiment, the adhesive joints 80C have a structure for connecting the upper I/O pad 202 of the printed circuit board 400 for semiconductor packaging to the lower I/O pad 60 of the second semiconductor device 100B.

The semiconductor device 304 having the warpage prevention adhesive pattern 70C according to certain embodiments, also may have variously modified structures as illustrated in FIGS. 6 through 8.

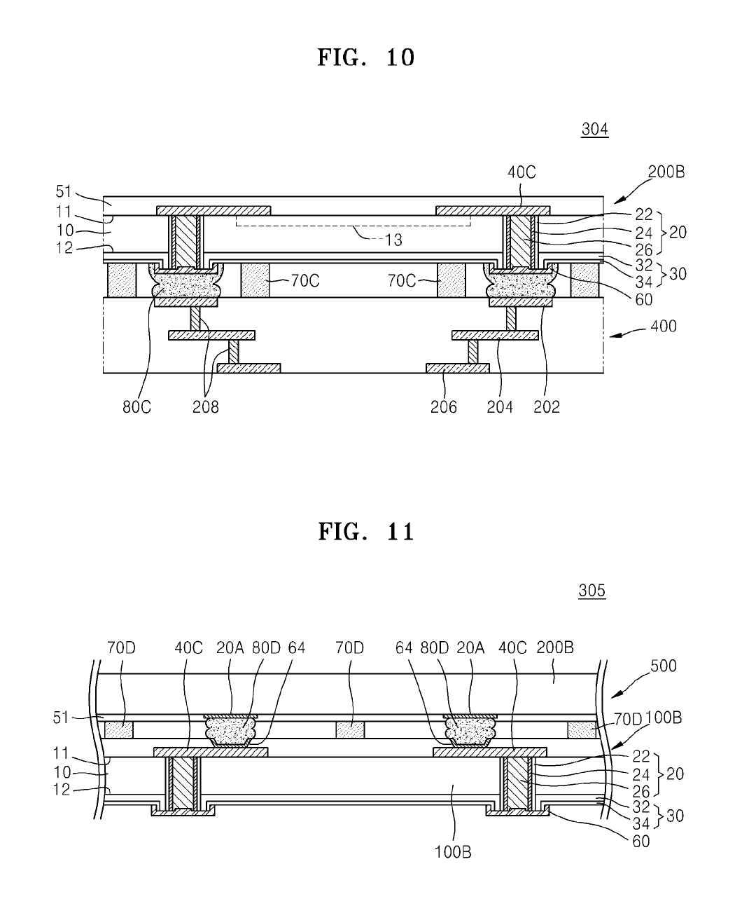

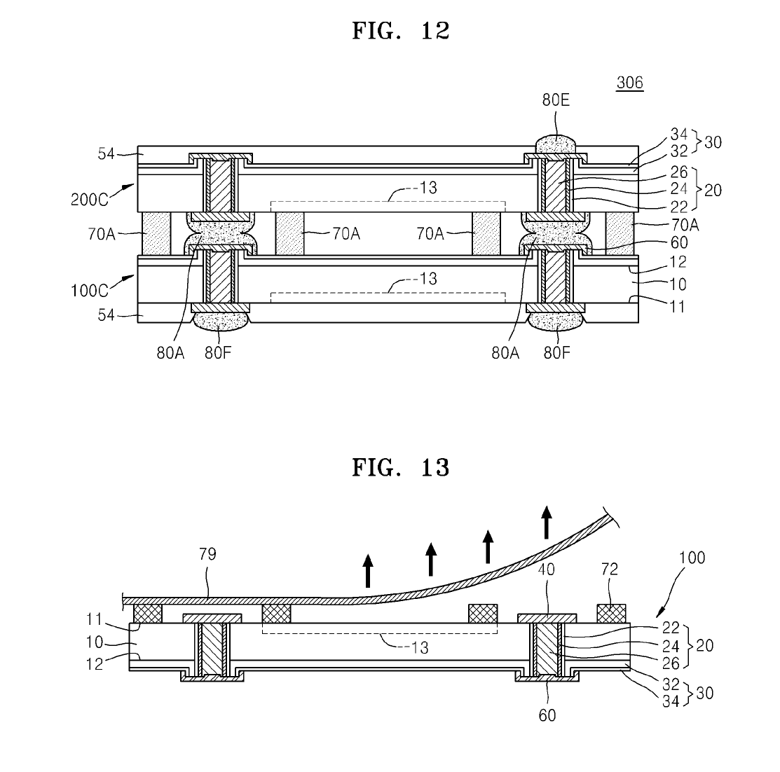

FIG. 11 is a cross-sectional view of a semiconductor device having a warpage prevention adhesive pattern according to another embodiment.

The semiconductor device 303 having the warpage prevention adhesive pattern 70B depicted in FIG. 9 shows a single semiconductor chip 200B as the second semiconductor device. However, referring to FIG. 11, a semiconductor device 305 having a warpage prevention adhesive pattern 70D according to another embodiment may use a wafer 500 having a bond pad 20A including a UBM layer, as the second semiconductor device.

Accordingly, in the semiconductor device 305 having the warpage prevention adhesive pattern 70D, the warpage prevention adhesive pattern 70D is formed between the first semiconductor device 100B whose state is a wafer state and the second semiconductor device 200B whose state is a wafer state, and the adhesive joints 80D are formed with a structure for the connecting pad rearranging pattern 40C of the first semiconductor device 100B and a bond pad 20A of the second semiconductor device 200B to each other. After the adhesive joints 80D are formed, individual stacks of chips may be singulated from the wafer. The remaining structure of the semiconductor device 305 is the same as those of the semiconductor devices 300 and 303 illustrated in FIGS. 5 and 9, and thus a detailed explanation thereof will be omitted here. Also, as described above, the embodiments depicted and discussed above may also refer to devices in either a singulated form or wafer form, even though the wafer form is not depicted in all of the drawings.

FIG. 12 is a cross-sectional view of a semiconductor device having a warpage prevention adhesive pattern according to another embodiment.

Referring to FIG. 12, a semiconductor device 306 having a warpage prevention adhesive pattern 70A may be designed with a structure for simultaneously forming the adhesive joints 80A and the other terminals, such as metal wirings 80E and 80F, during the electroless plating explained in FIG. 4. Here, the lower side of the first semiconductor device 100C and the upper side of the second semiconductor device 200C may be covered by a protection layer 54 including an insulation material.

The other metal wiring 80E may be a protrusion which is formed on the upper side of the second semiconductor device 200C and to which an additional item such as heat sink may be attached. The protrusion, that is, the other metal wiring 80E, may be formed by extending an electrical ground terminal of the second semiconductor device 200C located in the upper side, to the outside. Alternatively, the other metal wiring 80F may be a protrusion which is formed on the lower side of the first semiconductor device 100C and may be connected, for example, to a printed circuit board for semiconductor packaging. Accordingly, because it is possible to form metal wirings used in semiconductor packaging process by the electroless plating without needing a special process, it is possible to simplify a process and increase productivity.

FIGS. 13 through 15 are cross-sectional views for illustrating a method of fabricating a semiconductor device having a warpage prevention adhesive pattern according to another embodiment.

Referring to FIG. 13, a first semiconductor device 100 in which a circuit pattern 13 is formed on a semiconductor substrate 10, is prepared. Since the structure of the first semiconductor device 100 is the same as that of the first semiconductor device 100 illustrated in FIG. 1, a detailed explanation of the structure of the first semiconductor device 100 will be omitted here.

Next, a warpage prevention adhesive pattern 72 including an insulation material is attached on the first semiconductor device 100. According to the embodiment of FIGS. 1 through 4, the warpage prevention adhesive pattern 70A is formed by using a photolithography process. However, in the embodiment of FIGS. 13 through 15, the warpage prevention adhesive pattern 72, which may in one embodiment include a plurality of spacers in a pillar or other shape, is formed by directly attaching an adhesive layer or an adhesive pattern which is rolled up in the form of a roll 79, on the upper side 11 of the first semiconductor device 100. The warpage prevention adhesive pattern 72 may be a polymer including a material whose adhesive power is increased by heat. The rolled portion of the adhesive pattern may be easily removable from the spacers.

The height of the warpage prevention adhesive pattern 72 may be higher than that of the upper I/O pad 40 formed on the upper side of the first semiconductor device 100. Here, in the first semiconductor device 100, the lower side 12 of the semiconductor substrate 10 may be ground, that is, partially removed to implement a multi-chip package (MCP) or a system in package (SIP). The thickness of the ground first semiconductor device 100 may be the range of 30 μm through 120 μm, such that the ground first semiconductor device 100 may be very vulnerable to a warpage defect during handling or processing. Such vulnerability is largely avoided by using the warpage prevention adhesive pattern 72 depicted in FIG. 13.

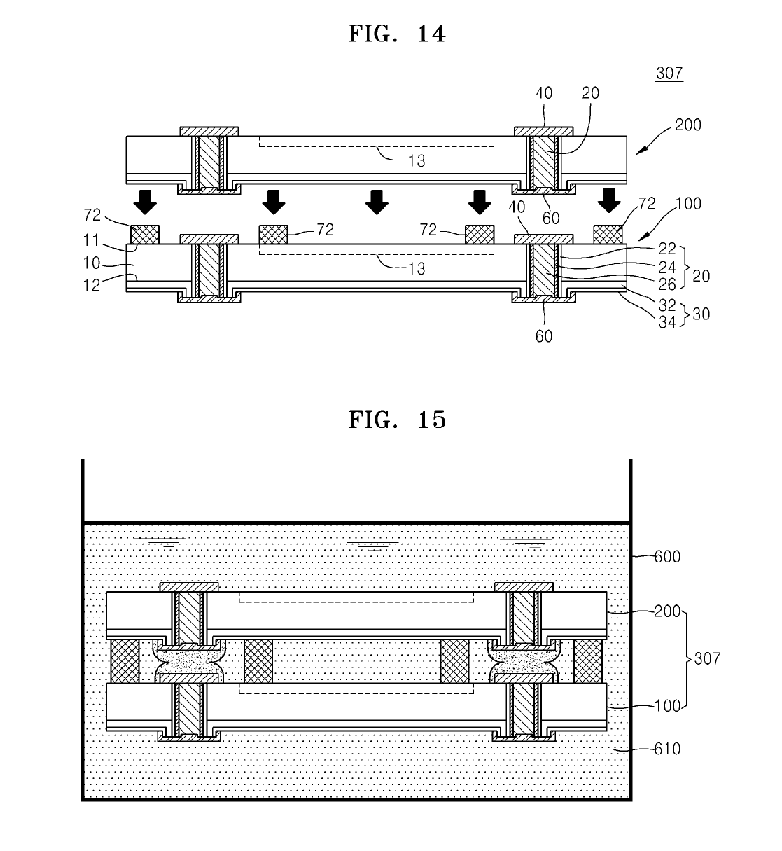

Referring to FIG. 14, a second semiconductor device 200 having the same structure as that of the first semiconductor device 100 is prepared. After that, two semiconductor devices 100 and 200 are lined up and connected on condition that the circuit patterns 13 of the semiconductor devices 100 and 200 are directed upward.

Here, the two semiconductor devices 100 and 200 may be lined up so that the lower I/O pad 60 of the second semiconductor device 200 may be aligned and exactly connected to the upper I/O pad 40 of the first semiconductor device 100. After the lineup, a curing process for applying heat to the two semiconductor devices 100 and 200 for a predetermined time, is performed. As a result, an adhesive power of the warpage prevention adhesive pattern 72 is strengthened by heat, and thus the two semiconductor devices 100 and 200 are physically stacked on each other.

An interval G1 is formed by the warpage prevention adhesive pattern 72 between the connected two semiconductor devices 100 and 200, and an interval G2 is generated between the lower I/O pad 60 of the second semiconductor device 200 and the upper I/O pad 40 of the first semiconductor device 100 (refer to FIG. 16). Here, the interval G1 and the interval G2 may be a large enough distance so that a plating liquid may permeate the space between the pads 40 and 60.

In one embodiment, the lower side 12 of the semiconductor substrate 10 is ground beforehand, and thus each of the first and second semiconductor devices 100 and 200 has the thickness of the range of 30 μm through 120 μm, which may be very vulnerable to the warpage defect. However, because the first and second semiconductor devices 100 and 200 are connected to each other by the warpage prevention adhesive pattern 72, the occurrence of the warpage defect may be suppressed during handling and processing of the semiconductor devices 100 and 200.

In this embodiment, the two semiconductor devices 100 and 200 are connected to each other so that the upper sides 11 of the semiconductor devices 100 and 200 are directed upward. However, the semiconductor devices 100 and 200 may be connected to each other so that the upper sides 11 of the semiconductor devices 100 and 200 are directed downward.

Next, performance of the electroless plating for the connected semiconductor devices 100 and 200 is prepared. In detail, except for the lower and upper I/O pads 60 and 40 disposed in the jointed sides of the first and second semiconductor devices 100 and 200, portions in which a conductive layer is formed, that is, the upper I/O pad 40 of the second semiconductor device 200 and the lower I/O pad 60 of the first semiconductor device 100 may be covered by a protection layer (not shown).

Referring to FIG. 15, a resulting product of FIG. 14 is put into a plating tub 600 where the electroless plating is performed. A plating liquid 610 including one of nickel, copper, silver, tin, chrome, and palladium may be prepared in the plating tub 600. After that, the electroless plating is performed for the connected first and second semiconductor devices 100 and 200.

As a result of the electroless plating, adhesive joints 80A (refer to FIG. 5) are formed in the lower side of the lower I/O pad 60 of the second semiconductor device 200 and in the upper side of the upper I/O pad 40 of the first semiconductor device 100, and thus the lower I/O pad 60 of the second semiconductor device 200 and the upper I/O pad 40 of the first semiconductor device 100 are connected to each other through the adhesive joints 80A.

FIGS. 16 is a cross-sectional view for illustrating a semiconductor device manufactured by using a method of fabricating a semiconductor device having a warpage prevention adhesive pattern according to one embodiment.

Referring to FIG. 16, a semiconductor device 307 having a warpage prevention adhesive pattern manufactured by using the fabricating method illustrated in FIGS. 13 through 15, may include a first semiconductor device 100, a second semiconductor device 200, a plurality of warpage prevention adhesive patterns 72, and a plurality of adhesive joints 80A.

The first semiconductor device 100 includes a circuit pattern 13 and an I/O pad 40 which is exposed in an upward direction, that is, in the upper side of the first semiconductor device 100. The second semiconductor device 200 is connected to the first semiconductor device 100 and separated from the first semiconductor device 100 by a predetermined interval G1, and includes an I/O pad 60 which is disposed in a downward direction.

The plurality of warpage prevention adhesive patterns 72 are disposed in the interval G1 between the first semiconductor device 100 and the second semiconductor device 200. The plurality of adhesive joints 80A are formed by the electroless plating, are disposed in a predetermined interval G2 between the first semiconductor device 100 and the second semiconductor device 200, and connect the lower I/O pad 60 of the second semiconductor device 200 and the upper I/O pad 40 of the first semiconductor device 100 to each other.

Compared with the embodiment of FIG. 5, in this embodiment of FIG. 16, the warpage prevention adhesive pattern 72 is formed by directly attaching an adhesive layer or an adhesive pattern which is rolled up in the form of a roll, on the upper side 11 of the first semiconductor device 100.

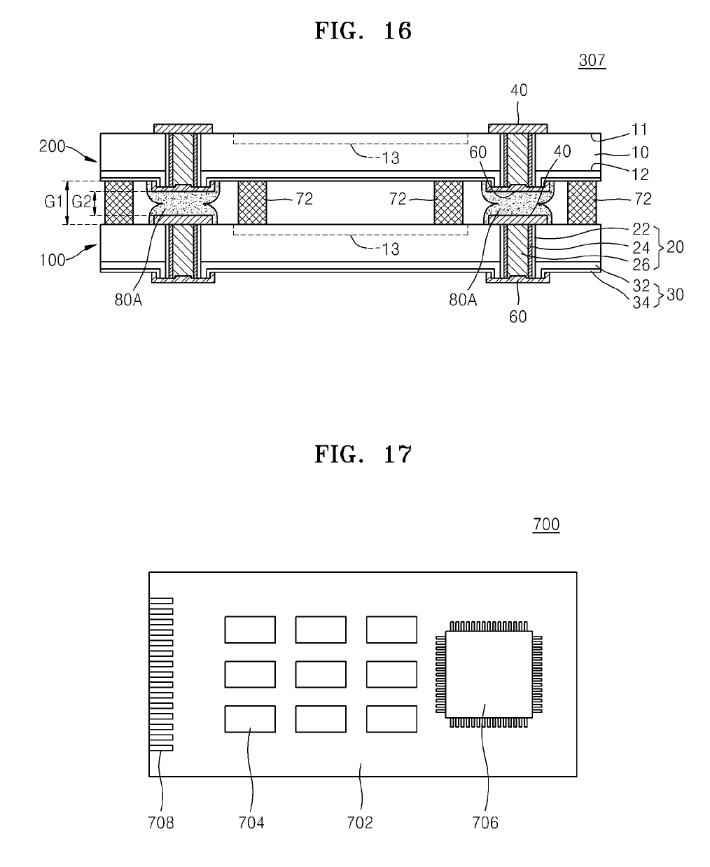

FIGS. 17 through 19 are a plan view and system block diagrams showing electronic devices to which a semiconductor device manufactured according to an embodiment of the inventive concept may be applied.

FIG. 17 is a plan view of a package module 700 according to an exemplary embodiment.

Referring to FIG. 17, the package module 700 may include a module substrate 702 having a connection terminal 708 for connecting to the outside, one or more semiconductor chips 704 mounted on the module substrate 702, and a semiconductor package 706 having a form of a quad flat package (QFP). In one embodiment, the semiconductor chips 704 and/or the semiconductor package 706 may include a semiconductor device according to one or more of the embodiments discussed previously. The package module 700 may be connected to an external electronic device through the connection terminal 708.

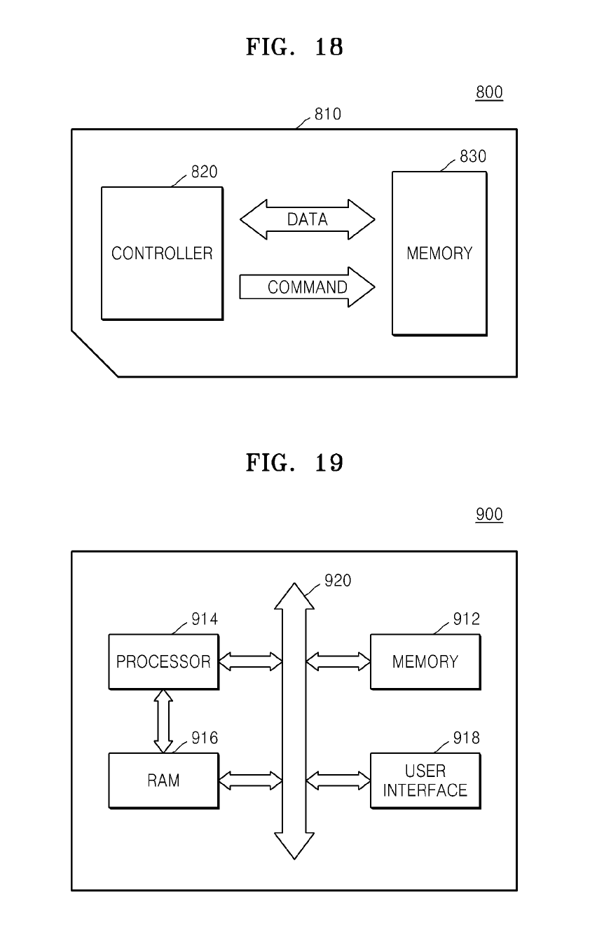

FIG. 18 is a schematic diagram showing a memory card 800 according to an exemplary embodiment.

Referring to FIG. 18, the memory card 800 may include a controller 820 and a memory 830 inside a housing 810.

The controller 820 and the memory 830 may exchange electrical signals. For example, the memory 830 and the controller 820 may exchange data in response to a command of the controller 820. Accordingly, the memory card 800 may store data in the memory 830 or may output data from the memory 830 to the outside. The controller 820 and the memory 830 may include at least one of a semiconductor device and a semiconductor package according to the above embodiments. The memory card 800 may be applied to a data storage medium of various types of portable equipment. For example, the memory card 800 may include a multi-media card (MMC) or a secure digital (SD) card.

FIG. 19 is a block diagram showing an electronic system 900 according to an exemplary embodiment.

Referring to FIG. 19, an electronic system 900 may include at least one of a semiconductor device and a semiconductor package according to the above embodiments. The electronic system 900 may include, for example, a mobile device or a computer. For example, the electronic system 900 may include a memory system 912, a processor 914, a random access memory RAM 916, and a user interface 918, and these elements may communicate with each other using a bus 920. The processor 914 may execute a program and control the electronic system 900. The RAM 916 may be used as an operation memory of the processor 914. For example, each of the memory system 912, the processor 914, and the RAM 916 may include a semiconductor device or a semiconductor package according to the embodiments described previously. In addition, the processor 914 and the RAM 916 may be included in a single package, or the memory system 912 and the RAM 916 may be included in a single package.

The user interface 918 may be used to input or output data in the electronic system 900. The memory system 912 may store codes for the operation of the processor 914, data processed by the processor 914, or data input from the outside. The memory system 912 may include a controller and a memory, and be configured to be substantially the same as the memory card 800 of FIG. 18. The electronic system 900 may be applied to electronic control devices of various types of electronic equipment.

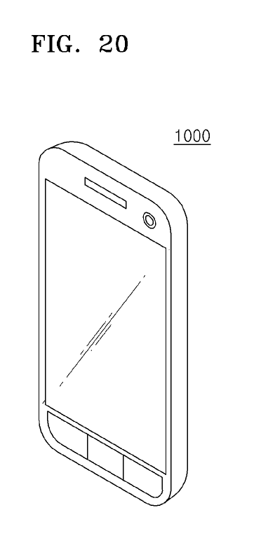

FIG. 20 is a perspective view showing an exemplary electronic device to which a semiconductor device fabricated by the disclosed embodiments may be applied. FIG. 20 illustrates an example in which the electronic system 900 is applied to a mobile phone 1000. In addition, the electronic system 900 may be applied to other devices, such as portable notebooks, MP3 players, navigation devices, solid state disks, automobiles, or household appliances.

While the disclosure has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. A semiconductor device, comprising:
a first device including a first substrate and a first external connection terminal for connecting outside the first device;
a second device stacked on the first device, the second device including a second substrate and a second external connection terminal for connecting outside the second device;
an adhesive pattern disposed between the first device and second device, the adhesive pattern disposed in locations other than locations where the first external connection terminal and second external connection terminal are disposed, and the adhesive pattern causing the first device and second device, when stacked, to be spaced apart by a predetermined distance; and
a plated layer disposed between and electrically and physically connecting the first external connection terminal and the second external connection terminal.

2. The semiconductor device of claim 1, wherein:
the first device is a first semiconductor chip, and the second device is one of a second semiconductor chip, a semiconductor package substrate, or a printed circuit board.

3. The semiconductor device of claim 2, wherein:
the first device is part of a first wafer; and
the second device is part of a second wafer.

4. The semiconductor device of claim 2, wherein:
the semiconductor device is a semiconductor package.

5. The semiconductor device of claim 1, wherein:
the adhesive pattern includes spacers that form a support structure separating the first device and the second device and prevent warping during a formation of the plated layer.

6. The semiconductor device of claim 5, wherein:
the adhesive pattern is a heat-treated pattern formed of an insulating material.

7. The semiconductor device of claim 1, wherein:
the plated layer is a layer formed by electroless plating; and
the plated layer contacts the first external connection terminal and the second connection terminal, and is confined laterally to a predetermined area so that it does not contact the adhesive pattern.

8. The semiconductor device of claim 1, wherein:
the first connection terminal includes a first conductive pad connected to an integrated circuit of the first device; and
the second connection terminal includes a second conductive pad connected to circuitry of the second device.

9. The semiconductor device of claim 8, further comprising:
a first through via passing through the first device and connecting the first conductive pad to the integrated circuit.

10. The semiconductor device of claim 1, further comprising:
the first device further including a third external connection terminal; and
the second device further including a fourth external connection terminal, wherein:
the plated layer is disposed between and electrically connects the third external connection terminal and the fourth external connection terminal.

11. The semiconductor device of claim 10, wherein:
the plated layer comprises a layer that forms electrical and physical connections between external connection terminals of the first device and respective external connection terminals of the second device vertically aligned with the external connection terminals of the first device; and
the plated layer is not formed where the adhesive pattern is disposed and is not formed in other spaces between the first device and the second device.

12. The semiconductor device of claim 11, wherein:
the plated layer is a layer formed by electroless plating.

13. A semiconductor package comprising:
a first substrate including a first external connection terminal disposed thereon;
a second substrate including a second external connection terminal disposed thereon;
a plated layer disposed between and electrically and physically connecting the first external connection terminal and the second external connection terminal; and
a support structure separating the first device and the second device by a predetermined distance, the support structure configured to prevent warping of the first and second substrate during a formation of the plated layer.

14. The semiconductor package of claim 13, wherein:
the first substrate is part of a first semiconductor chip; and
the second substrate is part of a second semiconductor chip or a package substrate.

15. The semiconductor package of claim 13, wherein:
the support structure includes spacers disposed between the first substrate and second substrate, the spacers disposed in locations other than locations where the first external connection terminal and second external connection terminal are disposed.

16. A method of fabricating a semiconductor device, the method comprising:
providing a first device including a first substrate and a first external connection terminal at a first surface of the first device;
forming spacers made of an insulating material on the first surface of the first device at a location other than a location where the first external connection terminal is disposed;
providing a second device stacked on the first device, the second device including a second substrate and a second external connection terminal at a first surface of the second device,
wherein the first surface of the first device faces the first surface of the second device, and
wherein the spacers cause the first device and second device, when stacked, to be spaced apart by a predetermined distance; and
forming a plated layer between the first external connection terminal and the second external connection terminal, the plated layer physically and electrically connecting the first external connection terminal and the second external connection terminal.

17. The method of claim 16, further comprising;
forming the plated layer by electroless plating after forming the spacers, wherein the forming of the spacers and the use of electroless plating prevent warping of the first device and the second device during the method of fabricating the semiconductor device.

18. The method of claim 16, wherein the first device additionally includes a third external connection terminal at the first surface of the first device and the second device additionally includes a fourth external connection terminal at the first surface of the second device and wherein forming the plated layer includes:
forming the plated layer between the first external connection terminal and the second external connection terminal at the same time as forming a plated layer between the third external connection terminal and the fourth external connection terminal, the plated layer physically and electrically connecting the first external connection terminal and the second external connection terminal, and physically and electrically connecting the third external connection terminal and the fourth external connection terminal.

19. The method of claim 18, further comprising:
forming the plated layer by subjecting the first device and second device to a plating liquid during an electroless plating process.

20. The method of claim 16, wherein:
the first device is a first semiconductor chip including an integrated circuit electrically connected to the first external connection terminal; and
the second device is a second semiconductor chip, a package substrate, or a printed circuit board.
